(19) United States
(12) Patent Application Publication
(10) Pub. No.: US 2019/0181222 A1
(43) Pub. Date: Jun. 13, 2019

(54) SEMICONDUCTOR MEMORY STRUCTURE AND METHOD FOR PREPARING THE SAME

(71) Applicant: NANYA TECHNOLOGY CORPORATION, NEW TAIPEI CITY (TW)

(72) Inventor: WEI-MING LIAO, TAOYUAN CITY (TW)

(21) Appl. No.: 15/835,940

(22) Filed: Dec. 8, 2017

(51) Int. Cl. H01L 29/06; H01L 27/108; H01L 27/02; H01L 21/3213

(52) U.S. Cl. CPC H01L 29/0642; H01L 27/10891; H01L 27/10855; H01L 27/10823; H01L 27/10885; H01L 21/32139; H01L 27/0207

(57) ABSTRACT

The present disclosure provides a semiconductor memory structure including a substrate including a first isolation structure and at least one active region defined by the first isolations structure, a second isolation structure disposed in the active region, a first buried word line and a second buried word line disposed in the second isolation structure, and at least one buried digit line disposed in the active region. Topmost portions of the first buried word line and the second buried word line are lower than a top surface of the second isolation structure, and a top surface of the buried digit line is lower than bottom surfaces of the first buried word line and the second buried word line.

### TECHNICAL FIELD

The present disclosure relates to a semiconductor memory structure and a method for preparing the same, and more particularly, to a semiconductor dynamic random access memory (DRAM) structure and a method for preparing the same.

### DISCUSSION OF THE BACKGROUND

Electrical products are becoming lighter, thinner, shorter, and smaller, and DRAMs are scaled down to match the trends of high integration and high density. A DRAM including many memory cells is one of the most popular volatile memory devices utilized today. Each memory cell includes a transistor and at least a capacitor, wherein the transistor and the capacitor form a series connection with each other. The memory cells are arranged into memory arrays. The memory cells are addressed via a word line and a digit line (or bit line), one of which addresses a “column” of memory cells while the other addresses a “row” of memory cells. By using the word line and the digit line, a DRAM cell can be read and programmed.

Recently, there has been increasing research on the buried word line cell array transistor in which a word line is buried in a semiconductor substrate below the top surface of the substrate using a metal as a gate conductor. However, as the reduction of the device size also reduces the distance between the word lines and the bit lines, word line disturbance is observed in adjacent word lines. When the word line disturbance becomes serious, performance of the DRAM cell is degraded.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a semiconductor memory structure. The semiconductor memory structure includes a substrate including a first isolation structure and at least one active region defined by the first isolation structure, a second isolation structure disposed in the active region, a first buried word line and a second buried word line disposed in the second isolation structure, and at least one buried digit line disposed in the active region. In some embodiments, topmost portions of the first buried word line and the second buried word line are lower than a top surface of the second isolation structure, and a top surface of the buried digit line is lower than bottom surfaces of the first buried word line and the second buried word line.

In some embodiments, the first buried word line and the second buried word line are electrically isolated from each other by the second isolation structure.

In some embodiments, the first buried word line and the second buried word line respectively include a spacer type conductive structure.

In some embodiments, each of the first buried word line and the second buried word line includes a first surface parallel with sidewalls of the second isolation structure, a second surface parallel with a bottom surface of the second isolation structure, and a sloped surface connecting the first surface and the second surface.

In some embodiments, the first buried word line and the second buried word line are electrically isolated from the active region by the second isolation structure.

In some embodiments, the semiconductor memory structure further includes a third isolation structure disposed between the second isolation structure and the buried digit line.

In some embodiments, the first buried word line and the second buried word line are electrically isolated from the buried digit line by the second isolation structure and the third isolation structure.

In some embodiments, a width of the buried digit line is less than a width of the second isolation structure.

In some embodiments, a minimum spacing distance between the first buried word line and the second buried word line is equal to or greater than the width of the buried digit line.

In some embodiments, a minimum spacing distance between the first buried word line and the second buried word line is less than the width of the buried digit line.

In some embodiments, the buried digit line extends in a first direction. In some embodiments, the first buried word line and the second buried word line extend in a second direction perpendicular to the first direction. In some embodiments, the active region extends in a third direction different from the first direction and the second direction.

Another aspect of the present disclosure provides a method for forming a semiconductor memory structure. The method includes the following steps. A substrate including an isolation structure for defining at least one active region is provided. A first trench is formed in the substrate. A buried digit line is formed in the first trench, wherein a top surface of the buried digit line is lower than a top surface of the active region. A second trench is formed over the buried digit line in the substrate. Subsequently, a first buried word line and a second buried word line are formed in the second trench. In some embodiments, topmost portions of the first buried word line and the second buried word line are lower than the top surface of the active region, and bottom surfaces of the first buried word line and the second buried word line are higher than the top surface of the buried digit line.

In some embodiments, the first trench extends in a first direction. In some embodiments, the second trench extends in a second direction perpendicular to the first direction. In some embodiments, the active region extends in a third direction different from the first direction and the second direction.

In some embodiments, a width of the second trench is greater than a width of the first trench. In some embodiments, a depth of the second trench is less than a depth of the first trench.

In some embodiments, the step of forming the buried digit line in the first trench further includes the following steps. A doped region is formed in the active region exposed through a bottom of the first trench. A first conductive material is formed in the first trench. In some embodiments, a top surface of the first conductive material is lower than an opening of the first trench. Subsequently, a first insulating material is formed to fill the first trench.

In some embodiments, the buried digit line is electrically isolated from the first buried word line and the second buried word line by at least the first insulating material.

In some embodiments, the step of forming the first buried word line and the second buried word line further includes the following steps. A second insulating material covering sidewalls and a bottom of the second trench is formed. A second conductive material is formed on the second insulating material. The second conductive material is etched back to form the first buried word line and the second buried word line spaced apart from each other in the second trench. A third insulating material is formed to fill the second trench.

In some embodiments, each of the first buried word line and the second buried word line includes a first surface parallel with sidewalls of the second trench, a second surface parallel with a bottom surface of the second trench, and a sloped surface connecting the first surface and the second surface.

In some embodiments, the first buried word line and the second buried word line are electrically isolated from the active region by the second insulating material and the third insulating material.

In some embodiments, the first buried word line and the second buried word line are electrically isolated from each other by the third insulating material.

In the present disclosure, a semiconductor memory structure including a first buried word line, a second buried word line and a buried digit line is provided. Using the first buried word line and the buried digit line, one DRAM cell is read and programmed. Similarly, using the second buried word line and the buried digit line, another DRAM cell is read and programmed. Further, even though the two DRAM cells share the same buried digit line, channel regions are still separated from each other because the second isolation structure provides electrical isolation between the first buried word line and the second buried word line. Consequently, word line disturbance is reduced.

In contrast, with a comparative DRAM memory structure, two word lines that share the same digit line also share the same channel region, and thus always suffer from word line disturbance.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a flow diagram illustrating a method for preparing a semiconductor memory structures in accordance with some embodiments of the present disclosure.

FIGS. 2A, 3A, 4A, 5A, 6A, 7A, 8A, 9A, 10A, 11A and 12A are schematic diagrams illustrating various fabrication stages of the method for preparing the semiconductor memory structure in accordance with some embodiments of the present disclosure.

FIGS. 2B, 3B, 4B, 5B, 6B, 7B, 8B, 9B, 10B, 11B and 12B are cross-sectional views taken along line I-I′ of FIGS. 2A, 3A, 4A, 5A, 6A, 7A, 8A, 9A, 10A, 11A and 12A, respectively.

FIG. 13 is a schematic drawing illustrating a portion of the semiconductor memory structure in accordance with some embodiments of the present disclosure.

FIG. 14 is a schematic drawing illustrating a portion of a semiconductor memory structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the ten is first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the terms “patterning” and “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etch or other removal process. The mask can be a photoresist, or a hard mask. In some embodiments, a patterning process is adopted to form a patterned layer directly on a surface. The patterning process includes forming a photosensitive film on the surface, conducting a photolithography process, and performing a developing process. The remaining photosensitive film is retained and integrated into the semiconductor device.

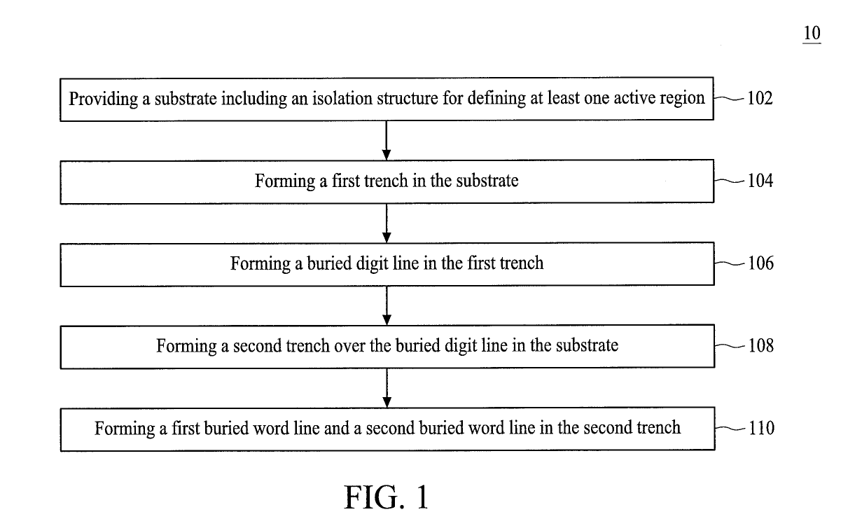

FIG. 1 is a flow diagram illustrating a method for preparing a semiconductor memory structure 10 in accordance with some embodiments of the present disclosure. The method for preparing the semiconductor memory structure 10 includes a step 102: Providing a substrate including an isolation structure for defining at least one active region. The method for preparing the semiconductor memory structure 10 further includes a step 104: forming a first trench in the substrate. The method for preparing the semiconductor memory structure 10 further includes a step 106: forming a buried digit line in the first trench. In some embodiments, a top surface of the buried digit line is lower than a top surface of the active region. The method for preparing the semiconductor memory structure 10 further includes a step 108: forming a second trench over the buried digit line in the substrate. The method for preparing the semiconductor memory structure 10 further includes a step 110: forming a first buried word line and a second buried word line in the second trench. The method for preparing the semiconductor memory structure 10 will be further described according to one or more embodiments.

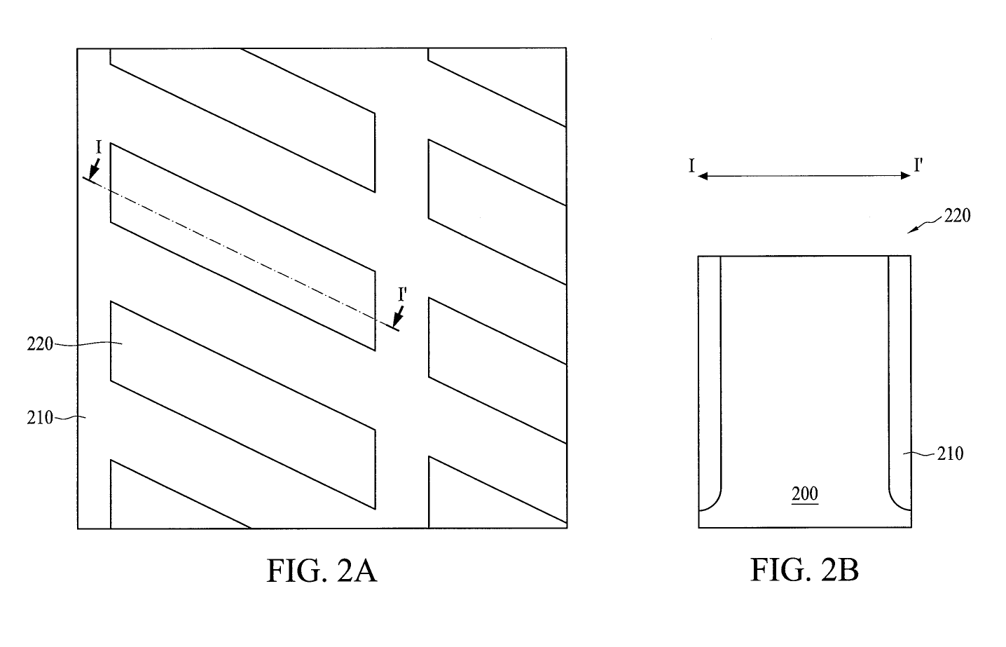

FIGS. 2A, 3A, 4A, 5A, 6A, 7A, 8A, 9A, 10A, 11A and 12A are schematic diagrams illustrating various fabrication stages of the method for preparing the semiconductor memory structure in accordance with some embodiments of the present disclosure, and FIGS. 2B, 3B, 4B, 5B, 6B, 7B, 8B, 9B, 10B, 11B and 12B are cross-sectional views taken along line I-I′ of FIGS. 2A, 3A, 4A, 5A, 6A, 7A, 8A, 9A, 10A, 11A and 12A, respectively. Referring to FIGS. 2A and 2B, a substrate 200 is provided according to step 102. In some embodiments, the substrate 200 includes a silicon substrate, a germanium substrate, or a silicon-germanium substrate, but the disclosure is not limited thereto. The substrate 200 includes an isolation structure 210 formed for defining at least one active region 220 according to step 102. In some embodiments, each active region 220 includes an island shape surrounded by the isolation structure 210 in a plan view, as shown in FIG. 2A. Accordingly, the active regions 220 may be arranged along rows and columns to form an array. In some embodiments, the isolation structure 210 can be formed by shallow trench isolation (STI) technique, but the disclosure is not limited thereto. For example, a shallow trench (not shown) can be formed in the substrate 200 in a form of grid, and insulating material such as silicon oxide (SiO), silicon nitride (SiN), and/or silicon oxynitride (SiON) is formed to fill the shallow trench. In some embodiments, an ion implantation can be selectively performed to implant boron (B) into the substrate 200 exposed through the shallow trench before filling the shallow trench with the insulating material for further improving electrical isolation, but the disclosure is not limited thereto. In some embodiments, an ion implantation for the well region can be performed after forming the isolation structure 210.

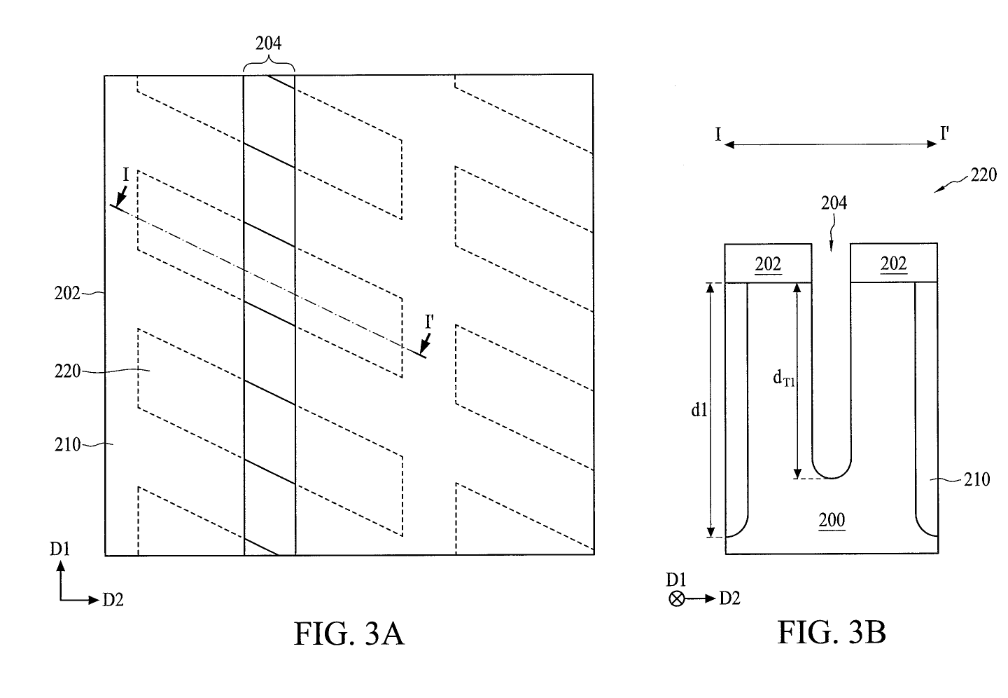

Next, a buried digit line 230 is formed in the substrate 200 according to step 104. In some embodiments, formation of the buried digit line 230 can further include the following steps. For example, a patterned hard mask 202 is formed on the substrate 200 and an etch process is performed to etch the substrate 200 through the patterned hard mask 202. Consequently, at least one first trench 204 is formed in the substrate 200. As shown in FIGS. 3A and 3B, the first trench 204 extends in a first direction D1. Further, portions of the first trench 204 are formed in the active region 220, and portions of the first trench 204 are formed in the isolation structure 210, as shown in FIG. 3A. In some embodiments, a depth d_{T1} of the first trench 204 is less than a depth d1 of isolation structure 210.

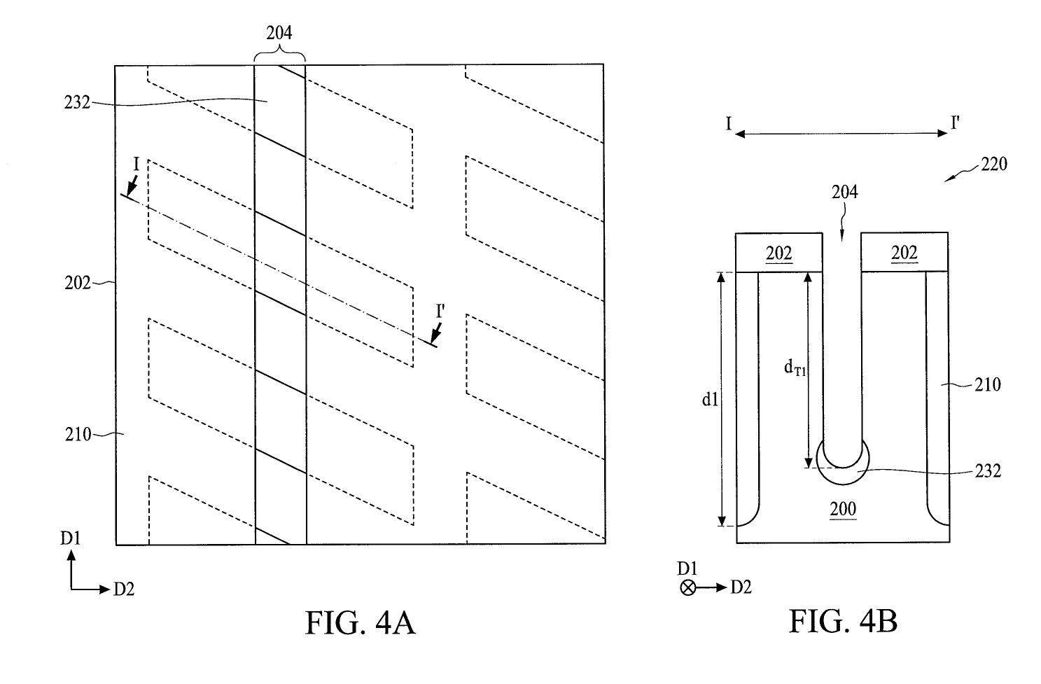

Referring to FIGS. 4A and 4B, an ion implantation is subsequently performed to form a doped region 232 in the active region 220 exposed through a bottom of the first trench 204. In some embodiments, the doped region 232 is heavily doped with arsenic (As), but the disclosure it not limited to this. The patterned hard mask 202 is removed after forming the doped region 232.

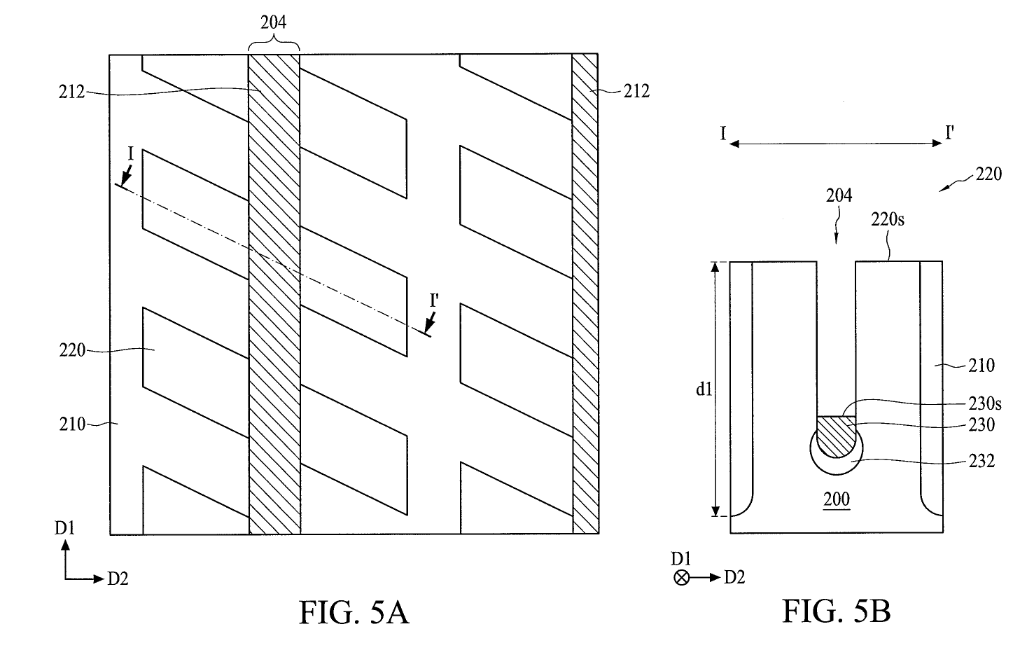

Referring to FIGS. 5A and 5B, next, a first conductive material is formed in the first trench 204. Accordingly, the first conductive material may be formed of any one of the group consisting of titanium nitride (TiN), titanium/titanium nitride (Ti/TiN), tungsten nitride (WN), tungsten/tungsten nitride (W/WN), tantalum nitride (TaN), tantalum/tantalum nitride (Ta/TaN), titanium silicon nitride (TiSiN), tantalum silicon nitride (TaSiN), tungsten silicon nitride (WSiN), or a combination thereof. The first conductive material may be formed using a chemical vapor deposition (CVD) or an atomic layer deposition (ALD) method. After forming the first conductive material, an etching process may be performed to recess the first conductive material. Accordingly, the buried digit line 230 is obtained. As shown in FIG. 5A, the buried digit line 230 extends in the first direction D1. Accordingly, portions of the buried digit line 230 are formed in the active regions 220, and portions of the buried digit line 230 are formed in the isolation structure 210. As shown in FIG. 5B, a top surface 230s of the buried digit line 230 is lower than an opening of the first trench 204.

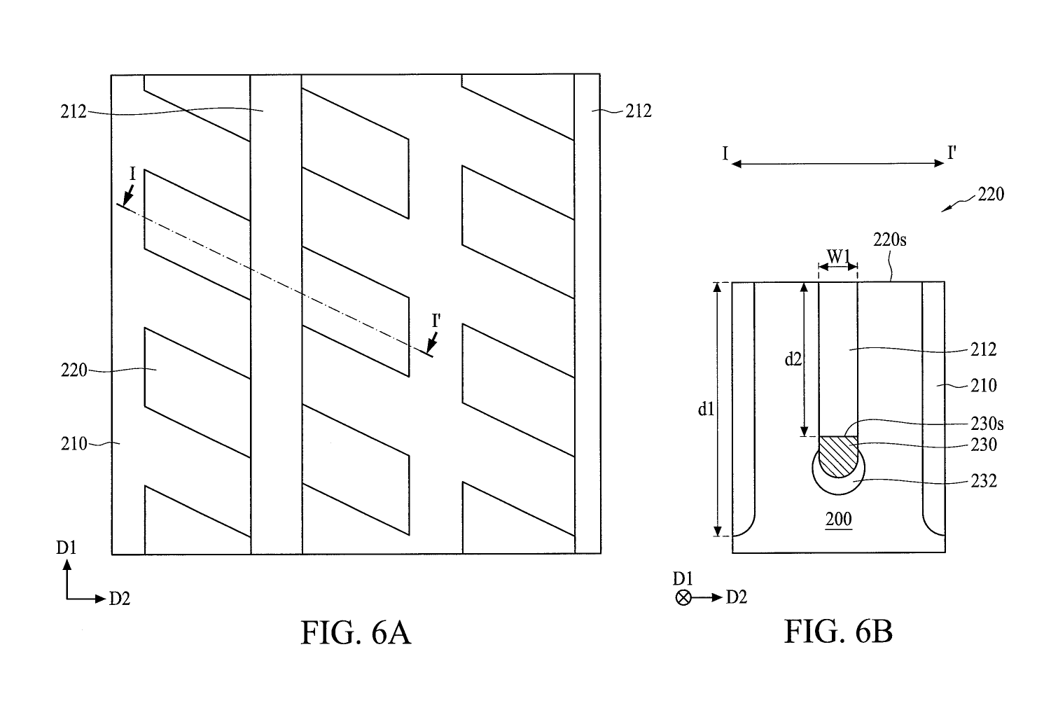

Referring to FIGS. 6A and 6B, after forming the buried digit line 230, a first insulating material is formed to fill the first trench 204. A planarization process can be subsequently performed to remove superfluous first insulating material from the substrate 200 and thus to form an isolation structure 212 in the first trench 204. Consequently, the buried digit line 230 is covered by the isolation structure 212, and the top surface 230a of the buried digit line 230 is lower than the top surface 220s of the active region 220. In some embodiments, the first insulating material includes insulating material different from material of the isolation structure 210. For example, when the isolation structure 210 includes SiO, the first insulating material can include SiN, but the disclosure is not limited thereto. As shown in FIG. 6A, the isolation structure 212 extends in the first direction D1. Further, since the buried digit line 230 and the isolation structure 212 are both formed in the first trench 204, the buried digit line 230, the isolation structure 212 and the first trench 204 include a same width W1, as shown in FIG. 6B.

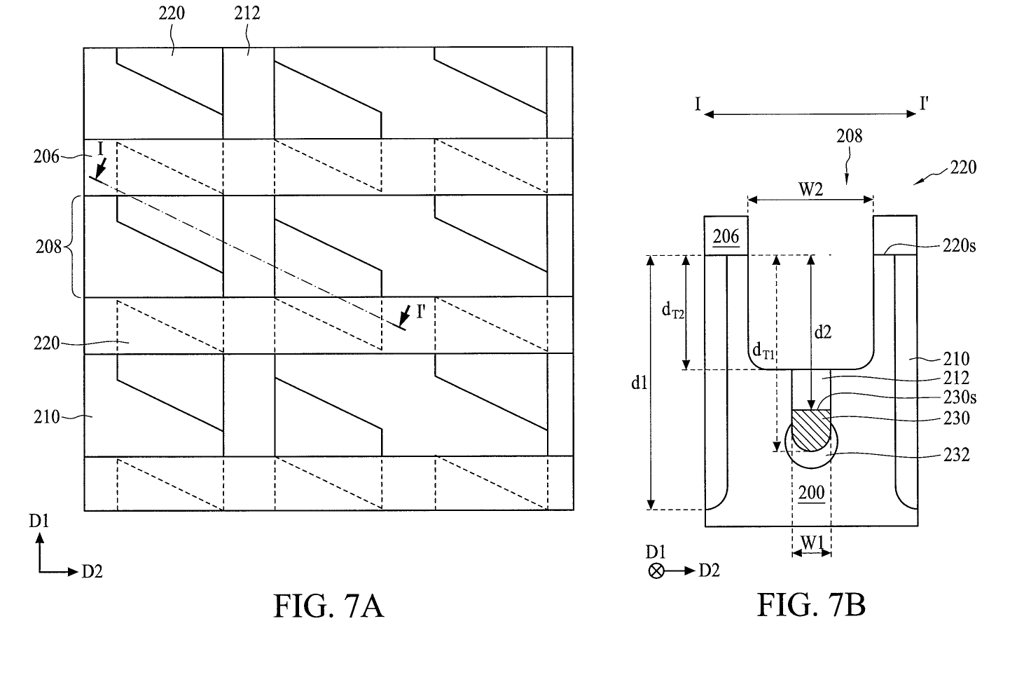

Referring to FIGS. 7A and 7B, a patterned hard mask 206 can be formed on the substrate 200, and an etch process is performed to etch the substrate 200 through the patterned hard mask 206. Consequently, at least one second trench 208 is formed in the substrate 200 according to step 108. Further, the second trench 208 is formed over the buried digit line 230 and the isolation structure 212. As shown in FIGS. 7A and 7B, the second trench 208 extends in a second direction D2. The second direction D2 is different from the first direction D1. In some embodiments, the second direction D2 is perpendicular to the first direction D1. Further, portions of the second trench 208 are formed in the active region 220, and portions of the second trench 208 are formed in the isolation structure 210, as shown in FIG. 7A. In some embodiments, a depth d_{T2} of the second trench 208 is less than the depth d1 of the isolation structure 210. In some embodiments, the depth d_{T2} of the second trench 208 is less than the depth d_{T1} (shown by the dotted line) of the first trench 204. In some embodiments, the depth d_{T2} of the second trench 208 is less than a depth d2 of the isolation structure 212, as shown in FIG. 7B. Further, a width W2 of the second trench 208 is greater than the width W1 of the buried digit line 230, the isolation structure 212 and the first trench 204. Additionally, the isolation structure 212 and a portion of the active region 220 are exposed through a bottom of the second trench 208, and a portion of the active region 220 is exposed through sidewalls of the second trench 208. Thereafter, the patterned hard mask 206 is removed.

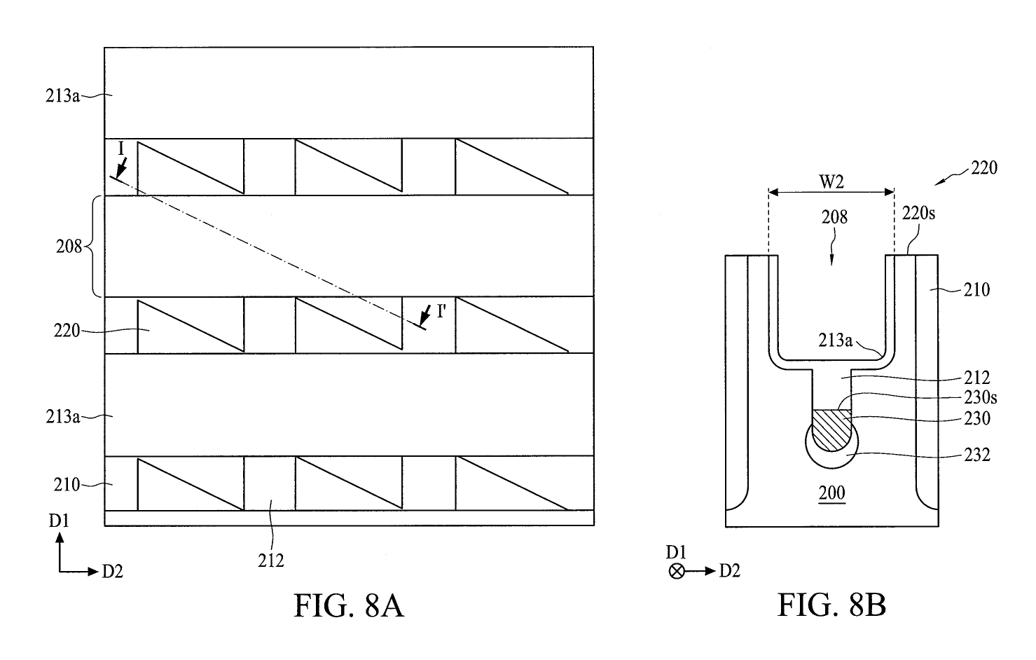

Next, a first buried word line 240a and a second buried word line 240b are formed in the second trench 208 according to step 110. In some embodiments, the formation of the buried word line 240a and the second buried word line 240b further includes the following steps. In some embodiments, a second insulating material 213a is formed in the second trench 208. As shown in FIGS. 8A and 8B, the second insulating material 213a covers the sidewalls and the bottom of the second trench 208. In some embodiments, the second insulating material 213a can include SiO, SiN, SiON, or high-k dielectric material. In some embodiments, the second insulating material 213a can be different from the first insulating material used to form the isolation structure 212. For example, the first insulating material can include SiN and the second insulating material 213a can include SiO, but the disclosure is not limited thereto. Additionally, the sidewalls and the bottom of the second trench 208 are covered by the second insulating material 213a, but the second trench 208 is not filled up, as shown in FIG. 8B.

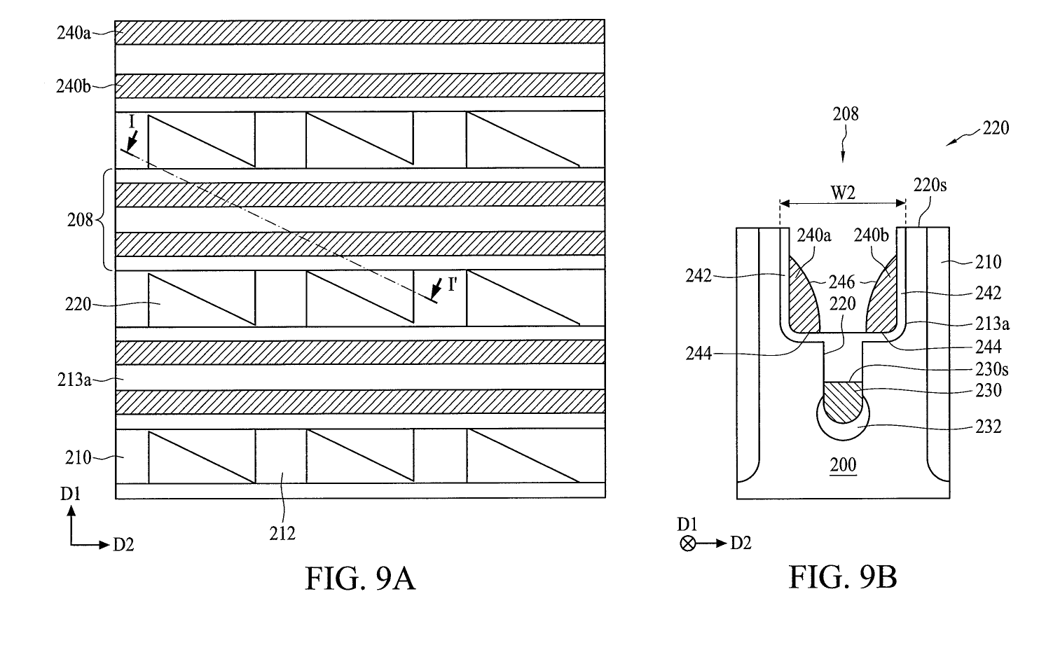

Referring to FIGS. 9A and 9B, a second conductive material is then formed in the second trench 208. In some embodiments, the second conductive material can be formed of any one of the group consisting of TiN, Ti/TiN, WN, W/WN, TaN, Ta/TaN, TiSiN, TaSiN, WSiN, or a combination thereof. The second conductive material may be formed using a CVD or an ALD method. After forming the second conductive material, an etching process may be performed to recess the second conductive material. Accordingly, the first buried word line 240a and the second buried word line 240b are formed in the second trench 208. Each of the first buried word line 240a and the second buried word line 240b are in the form of a sidewall spacer type, as shown in FIG. 9B. In other words, the first buried word line 240a and the second buried word line 240b respectively include a spacer type conductive structure. Further, the first buried word line 240a and the second buried word line 240b are spaced apart from each other. Topmost portions of the first buried word line 240a and the second buried word line 240b are lower than an opening of the second trench 208. Alternatively, the topmost portions of the first buried word line 240a and the second buried word line 240b are lower than the top surface 220s of the active region 220. However, bottom surfaces of the first buried word line 240a and the second buried word line 240b are higher than the top surface 230s of the buried digit line 230.

Still referring to FIGS. 9A and 9B, as shown in FIG. 9A, the first buried word line 240a and the second buried word line 240b both extend in the second direction D2. In other words, the first buried word line 240a and the second buried word line 240b are perpendicular to the buried digit line 230. As shown in FIG. 9B, each of the first buried word line 240a and the second buried word line 240b includes a first surface 242 parallel with the sidewalls of the second trench 208, a second surface 244 parallel with a bottom surface of the second trench 208, and a sloped surface 246 connecting the first surface 242 and the second surface 244.

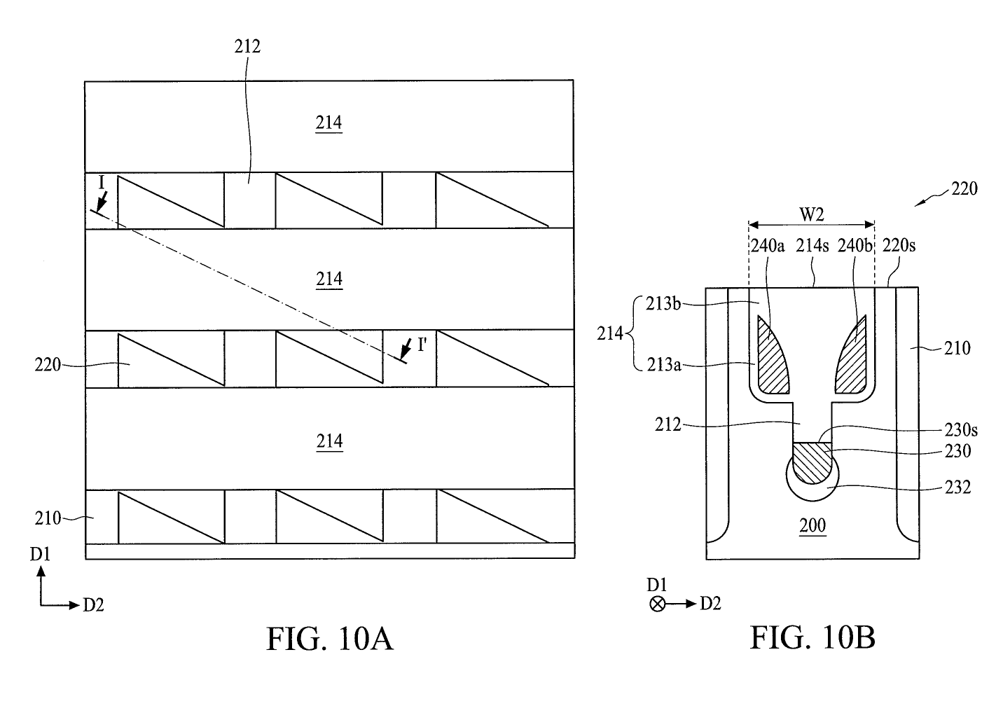

Referring to FIGS. 10A and 10B, a third insulating material 213b is formed to fill the second trench 208. In some embodiments, the third insulating material 213b and the second insulating material 213a can include the same material, but the disclosure is not limited thereto. A planarization process can be performed to remove superfluous third insulating material from the substrate 200 and thus to form an isolation structure 214 including the second insulating material 213a and the third insulating material 213b in the second trench 208. As shown in FIG. 10A, the isolation structure 214 extends in the second direction D2. As shown in FIG. 10B, the third insulating material 213b covers the first buried word line 240a and the second buried word line 240b. In other words, the first buried word line 240a and the second buried word line 240b are entirely embedded and enclosed in the isolation structure 214.

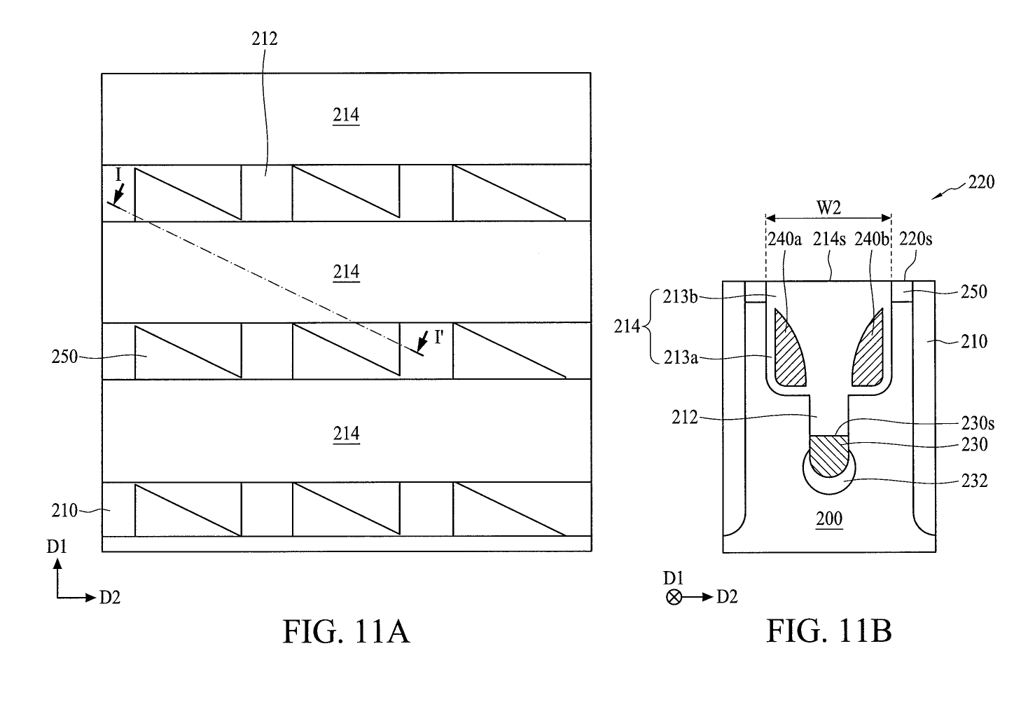

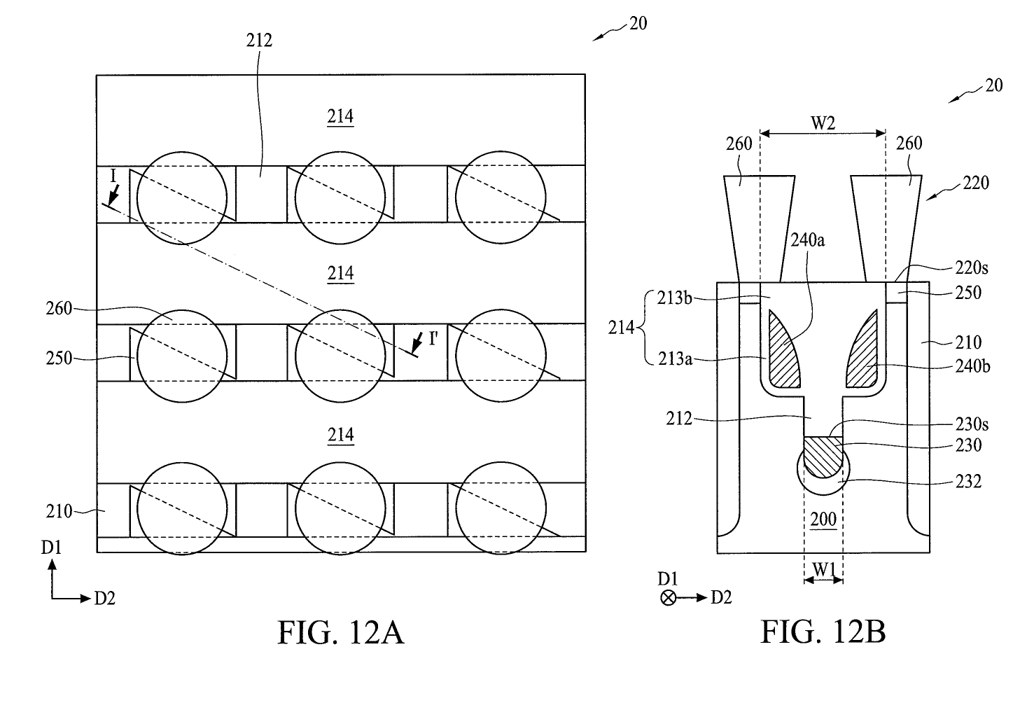

Referring to FIGS. 11A and 11B, doped regions 250 are formed in each active region 220. In some embodiments, an ion implantation is performed to form the doped regions 250 in the active region 220 exposed through the isolation structure 210 and the isolation structure 214. In some embodiments, the doped regions 250 are heavily doped with arsenic, but the disclosure it not limited to this. Referring to FIGS. 12A and 12B, contact plugs 260 are then formed on the doped regions 250.

Accordingly, a semiconductor memory structure 20 is provided. In some embodiments, the semiconductor memory structure 20 includes the substrate 200 including the isolation structure 210 and at least one active region 220 defined by the isolation structure 210, the isolation structure 214 disposed in the active region 220, the first buried word line 240a and the second buried word line 240b disposed in the isolation structure 214, and the buried digit line 230 disposed in the active region 220. In some embodiments, the buried digit line 230 is disposed under the first buried word line 240a and the second buried word line 240b. In some embodiments, the topmost portions of the first buried word line 240a and the second buried word line 240b are lower than a top surface 214s of the isolation structure 214 and the top surface 220s of the active region 220. As mentioned above, the top surface 230s of the buried digit line 230 is lower than the bottom surfaces of the first buried word line 240a and the second buried word line 240b. Further, the buried digit line 230 is disposed between the first buried word line 240a and the second buried word line 240b from a perspective plan view.

The buried digit line 230 extends in the first direction D1, and the first buried word line 240a and the second buried word line 240b extend in the second direction D2. As mentioned above, the first direction D1 is perpendicular to the second direction D2. Further, the active region 220 extends in a third direction D3 different from the first direction D1 and the second direction D2. Referring to FIG. 12B, the first buried word line 240a and the second buried word line 240b are spaced apart and electrically isolated from each other by the isolation structure 214. In some embodiments, the first buried word line 240a and the second buried word line 240b are spaced apart and electrically isolated from each other by the third insulating material 213b of the isolation structure 214. Further, the first buried word line 240a and the second buried word line 240b are spaced apart and electrically isolated from the active region 220 by the isolation structure 214. In some embodiments, the first buried word line 240a and the second buried word line 240b are spaced apart and electrically isolated from the active region 220 by the second insulating material 213a and the third insulating material 213b of the isolation structure 214. In some embodiments, the first buried word line 240a and the second buried word line 240b are spaced apart and electrically isolated from the buried digit line 230 by the isolation structure 214 and the isolation structure 212. In other words, the first buried word line 240a and the second buried word line 240b are spaced apart and electrically isolated from the buried digit line 230 by the first insulating material and the isolation structure 214. Further, the width W1 of the buried digit line 230 is less than the width W2 of the isolation structure 214. In some embodiments, the depth d1 of the isolation structure 210 is greater than the depth d2 of the isolation structure 212, and the depth d2 of the isolation structure 212 is greater than a depth d3 of the isolation structure 214, but the disclosure is not limited thereto.

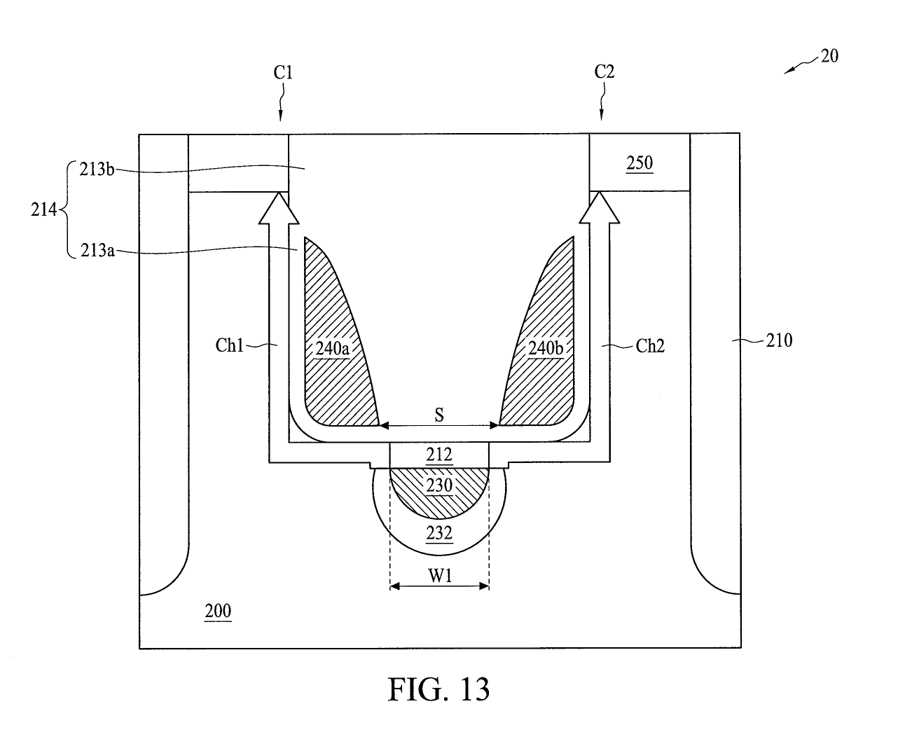

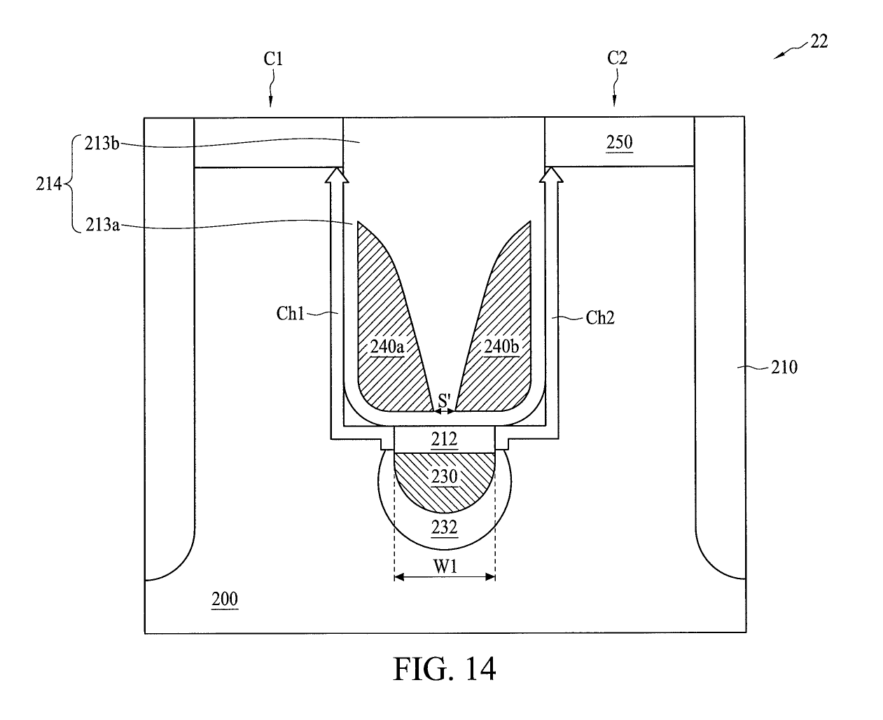

Referring to FIGS. 13 and 14, FIG. 13 is a schematic drawing illustrating a portion of the semiconductor memory structure 20, and FIG. 14 is a schematic drawing illustrating a portion of the semiconductor memory structure 22 in accordance with some embodiments of the present disclosure. It should be noted that similar elements in FIGS. 13 and 14 can include similar materials and can be formed by similar steps; therefore such details are omitted in the interest of brevity. In some embodiments, a minimum spacing distance S between the first buried word line 240a and the second buried word line 240b is equal to or greater than the width W1 of the buried digit line 230 as shown in FIG. 13. In some embodiments, a minimum spacing distance S′ between the first buried word line 240a and the second buried word line 240b is less than the width W1 of the buried digit line 230 as shown in FIG. 14. In other words, at least a portion of the first buried word line 240a and at least a portion of the second buried word line 240b overlap the buried digit line 230 in some embodiments, but the disclosure is not limited thereto. It can be easily realized that the minimum spacing distance S or S′ between the first buried word line 240a and the second buried word line 240b can be adjusted depending on the width W2 of the second trench 208 or the width W2 of the second isolation 214. In some embodiments, as shown in FIG. 13, by increasing the width W2 of the isolation structure 214, the minimum spacing distance S is increased, and thus the process widow for forming the first buried word line 240a and the second buried word line 240b is improved. In some embodiments as shown in FIG. 14, by reducing the width W2 of the isolation structure 214, the minimum spacing distance S′ is reduced. However, more a larger active region 220 is exposed through the isolation structure 214 and thus the area for forming the doped region 250 is increased.

In the present disclosure, the method for preparing the semiconductor memory structure 10 can be performed to form two DRAM cells C1 and C2. By using the first buried word line 240a and the buried digit line 230, the DRAM cell C1 can be read and programmed. Similarly, by using the second buried word line 240b and the buried digit line 230, the DRAM cell C2 can be read and programmed. Therefore, the buried digit line 230 is shared by the two DRAM cells C1 and C2. However, a channel region Ch1 of the DRAM cell C1 and a channel region Ch2 are separated from each other by the isolation structure 214, and by the first and second buried word lines 240a and 240b as shown in FIGS. 13 and 14. Since the channel regions Ch1 and Ch2 are no longer adjacent to each other, the word line disturbance issue is mitigated. Further, since the buried digit line 230 is spaced apart and electrically isolated from the first buried word line 240a and the second buried word line 240b, BL-Cell parasitic capacitance is reduced. Referring back to FIGS. 12A and 12B, since all the word lines and digit lines are buried under the top surface 220s of the active region 220, more spaces are obtained for positioning the contact plugs 260 and container-shaped storage node structures, and thus process window and reliability are both improved. Further, since the major channel regions Ch1 and Ch2 are along the sidewalls of the isolation structure 214 as shown in FIGS. 13 and 14, the channel length of the DRAM cells C1 and C2 can be easily adjusted by modifying the depth d_{T2} of the second trench 208 or the depth d3 of the isolation structure 214. Additionally, the method for preparing the semiconductor memory structure 10 can be easily integrated in the semiconductor process. Briefly speaking, the method for preparing the semiconductor memory structure 10 not only improves process window, but also provides the semiconductor memory structure 20 with improved performance and reliability.

In contrast, with a comparative DRAM memory structure, the two word lines that share the same digit line also share the same channel region, and thus always suffer word line disturbance. The comparative DRAM memory structure therefore suffers from inferior performance.

One aspect of the present disclosure provides a semiconductor memory structure. The semiconductor memory structure includes a substrate including a first isolation structure and at least one active region defined by the first isolation structure, a second isolation structure disposed in the active region, a first buried word line and a second buried word line disposed in the second isolation structure, and at least one buried digit line disposed in the active region. In some embodiments, topmost portions of the first buried word line and the second buried word line are lower than a top surface of the second isolation structure, and a top surface of the buried digit line is lower than bottom surfaces of the first buried word line and the second buried word line.

One aspect of the present disclosure provides a method for forming a semiconductor memory structure. The method includes the following steps. A substrate including an isolation structure for defining at least one active region is provided. A first trench is formed in the substrate. A buried digit line is formed in the first trench, and a top surface of the buried digit line is lower than a top surface of the active region. A second trench is formed over the buried digit line in the substrate. Subsequently, a first buried word line and a second buried word line are formed in the second trench. In some embodiments, topmost portions of the first buried word line and the second buried word line are lower than the top surface of the active region, and bottom surfaces of the first buried word line and the second buried word line are higher than the top surface of the buried digit line.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor memory structure comprising:
a substrate comprising a first isolation structure and at least one active region defined by the first isolation structure;
a second isolation structure disposed in the active region;
a first buried word line and a second buried word line disposed in the second isolation structure, wherein topmost portions of the first buried word line and the second buried word line are lower than a top surface of the second isolation structure; and
at least one buried digit line disposed in the active region, wherein a top surface of the buried digit line is lower than bottom surfaces of the first buried word line and the second buried word line.

2. The semiconductor memory structure of claim 1, wherein the first buried word line and the second buried word line are electrically isolated from each other by the second isolation structure.

3. The semiconductor memory structure of claim 1, wherein the first buried word line and the second buried word line respectively comprise a spacer type conductive structure.

4. The semiconductor memory structure of claim 3, wherein each of the first buried word line and the second buried word line comprises a first surface parallel with sidewalls of the second isolation structure, a second surface parallel with a bottom surface of the second isolation structure, and a sloped surface connecting the first surface and the second surface.

5. The semiconductor memory structure of claim 1, wherein the first buried word line and the second buried word line are electrically isolated from the active region by the second isolation structure.

6. The semiconductor memory structure of claim 1, further comprising a third isolation structure disposed between the second isolation structure and the buried digit line.

7. The semiconductor memory structure of claim 6, wherein the first buried word line and the second buried word line are electrically isolated from the buried digit line by the second isolation structure and the third isolation structure.

8. The semiconductor memory structure of claim 1, wherein a width of the buried digit line is less than a width of the second isolation structure.

9. The semiconductor memory structure of claim 1, wherein a minimum spacing distance between bottoms of the first buried word line and the second buried word line is equal to or greater than the width of the buried digit line.

10. The semiconductor memory structure of claim 1, wherein a minimum spacing distance between the first buried word line and the second buried word line is less than the width of the buried digit line.

11. The semiconductor memory structure of claim 1, wherein the buried digit line extends in a first direction, the first buried word line and the second buried word line extend in a second direction perpendicular to the first direction, and the active region extends in a third direction different from the first direction and the second direction.

12. A method for preparing a semiconductor memory structure, comprising:
providing a substrate comprising an isolation structure for defining at least one active region;
forming a first trench in the substrate;
forming a buried digit line in the first trench, wherein a top surface of the buried digit line is lower than a top surface of the active region;
forming a second trench over the buried digit line in the substrate; and
forming a first buried word line and a second buried word line in the second trench,
wherein topmost portions of the first buried word line and the second buried word line are lower than the top surface of the active region, and bottom surfaces of the first buried word line and the second buried word line are higher than the top surface of the buried digit line.

13. The method of claim 12, wherein the first trench extends in a first direction, the second trench extends in a second direction perpendicular to the first direction, and the active region extends in a third direction different from the first direction and the second direction.

14. The method of claim 12, wherein a width of the second trench is greater than a width of the first trench, and a depth of the second trench is less than a depth of the first trench.

15. The method of claim 12, wherein the step of forming the buried digit line in the first trench further comprises:
forming a doped region in the active region exposed through a bottom of the first trench;
forming a first conductive material in the first trench, a top surface of the first conductive material being lower than an opening of the first trench; and
forming a first insulating material to fill the first trench.

16. The semiconductor memory structure of claim 15, wherein the buried digit line is electrically isolated from the first buried word line and the second buried word line by at least the first insulating material.

17. The method of claim 12, wherein the step of forming the first buried word line and the second buried word line further comprises:
forming a second insulating material covering sidewalls and a bottom of the second trench;
forming a second conductive material on the second insulating material;
etching the second conductive material to form the first buried word line and the second buried word line spaced apart from each other in the second trench; and
forming a third insulating material to fill the second trench.

18. The method of claim 17, wherein each of the first buried word line and the second buried word line comprises a first surface parallel with the sidewalls of the second trench, a second surface parallel with a bottom surface of the second trench, and a sloped surface connecting the first surface and the second surface.

19. The method of claim 17, wherein the first buried word line and the second buried word line are electrically isolated from the active region by the second insulating material and the third insulating material.

20. The method of claim 17, wherein the first buried word line and the second buried word line are electrically isolated from each other by the third insulating material.
